(19) United States
(12) Patent Application Publication
(10) Pub. No.: US 2013/0298942 A1
(43) Pub. Date: Nov. 14, 2013

(54) ETCH REMNANT REMOVAL

(71) Applicant: APPLIED MATERIALS, INC., Santa Clara, CA (US)

(72) Inventors: He Ren, San Jose, CA (US); Nitin K. Ingle, San Jose, CA (US); Anchuan Wang, San Jose, CA (US)

(73) Assignee: Applied Materials, Inc., Santa Clara, CA (US)

(21) Appl. No.: 13/791,372

(22) Filed: Mar. 8, 2013

Related U.S. Application Data
(60) Provisional application No. 61/646,607, filed on May 14, 2012.

(51) Int. Cl. H01L 21/02

(52) U.S. Cl. CPC H01L 21/0206
USPC 134/1.2

(57) ABSTRACT

Methods of removing residual polymer from vertical walls of a patterned dielectric layer are described. The methods involve the use of a gas phase etch to remove the residual polymer without substantially disturbing the patterned dielectric layer. The gas phase etch may be used on a patterned low-k dielectric layer and may maintain the low dielectric constant of the patterned dielectric layer. The gas phase etch may further avoid stressing the patterned low-k dielectric layer by avoiding the use of liquid etchants whose surface tension can upset delicate low-K features. The gas phase etch may further avoid the formation of solid etch by-products which cars also deform the delicate features.

### CROSS-REFERENCES TO RELATED APPLICATIONS

This application claims the benefit of U.S. Prov. Pat. App. No. 61/646,607 filed May 14, 2012, and titled “ETCH REMNANT REMOVAL,” which is incorporated in its entirety herein by reference for all purposes.

### BACKGROUND OF THE INVENTION

Integrated circuit fabrication methods have reached a point where many hundreds of millions of transistors are routinely formed on a single chip. Each new generation of fabrication techniques and equipment are allowing commercial scale fabrication of ever smaller and faster transistors. However, each new generation also increases the degree of difficulty involved in making the new circuit elements. The shrinking dimensions of circuit elements, now well below the 50 nm threshold, has caused chip designers to look for new low-resistivity conductive materials and new low-dielectric constant (i.e., low-k) insulating materials to improve (or simply maintain) the electrical performance of the integrated circuit.

Parasitic capacitance becomes a significant impediment to transistor switching rate as the density of transistors is increased. Capacitance exists between all adjacent electrically isolated conductors within an integrated circuit and may limit the switching rate regardless of whether the conducting portions are at the “front end” or the “back end” of the manufacturing process flow. The dielectric material inserted between adjacent electrically isolated conductors can be made with a low dielectric constant in order to limit the parasitic capacitance. The structural resilience of low-K dielectric material is less than alternative dielectrics, such as silicon oxide.

These low-K dielectric materials often must be patterned using photolithography and an etch process. The etch process generally deposits polymer (CₓF_{y}) on the sidewalls of a trench during the etch, in order to encourage the etch to proceed downward rather than isotropically. Current methods of removing the residual polymer involve liquid etchant or a dry oxygen etch.

The liquid etchants can damage narrow low-K dielectric lines as a result of their lower structural integrity. Oxygen-based dry etchs, on the other hand, can measurably increase the dielectric constant of the low-K material.

Methods are needed to remove residual polymer from patterned low-K dielectric layers without toppling or otherwise damaging intricate low-K features and without substantially increasing the effective dielectric constant.

### BRIEF SUMMARY OF THE INVENTION

Methods of removing residual polymer from vertical walls of a patterned dielectric layer are described. The methods involve the use of a gas phase etch to remove the residual polymer without substantially disturbing the patterned dielectric layer. The gas phase etch may be used on a patterned low-k dielectric layer and may maintain the low dielectric constant of the patterned dielectric layer. The gas phase etch may further avoid stressing the patterned low-k dielectric layer by avoiding the use of liquid etchants whose surface tension can upset delicate low-K features. The gas phase etch may further avoid the formation of solid etch by-products which can also deform the delicate features.

Embodiments of the invention include methods of removing polymer residue from a patterned substrate in a substrate processing region of a substrate processing chamber. The method includes flowing a hydrogen-containing precursor into a remote plasma region fluidly coupled to the substrate processing region while forming a remote plasma in the remote plasma region to produce plasma effluents. The method further includes removing the polymer residue by flowing the plasma effluents into fire substrate processing region.

Embodiments of the invention also include methods of removing polymer residue from a patterned substrate in a substrate processing region of a substrate processing chamber. The methods comprise flowing a fluorine-containing precursor into a remote plasma region fluidly coupled to the substrate processing region while forming a remote plasma in the remote plasma region to produce plasma effluents. The methods further include flowing a hydrogen-containing precursor into the substrate processing chamber. The hydrogen-containing precursor flows directly into the substrate processing region without first passing through the remote plasma region. The methods further include removing the polymer residue by combining the plasma effluents with the hydrogen-containing precursor in the substrate processing region.

Additional embodiments and features are set forth in part in the description that follows, and in part will become apparent to those skilled in the art upon examination of the specification or may be learned by the practice of me disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIGS. 1A-1B are flow charts of etch residue removal processes according to disclosed embodiments.

FIG. 2 snows dielectric constant and residue removal efficiency for different conditions of the removal process according to embodiments of the invention.

FIG. 3A is a schematic of a top SEM view of low-K dielectric lines with etch residue present.

FIG. 3B is a schematic of a top SEM view of low-K dielectric lines after the etch residue has been removed with a removal process according to embodiments of the invention.

FIG. 4A shows a substrate processing chamber according to embodiments of the invention.

FIG. 4B shows a showerhead of a substrate processing chamber according in embodiments of the invention.

FIG. 5 shows a substrate processing system according to embodiments of the invention.

In the appended figures, similar components and/or features may nave the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of removing residual polymer from vertical walls of a patterned dielectric layer are described. The methods involve the use of a gas phase etch to remove the residual polymer without substantially disturbing the patterned dielectric layer. The gas phase etch may be used on a patterned low-k dielectric layer and may maintain the low dielectric constant of the patterned dielectric layer. The gas phase etch may further avoid stressing the patterned low-k dielectric layer by avoiding the use of liquid etchants whose surface tension can upset delicate low-K features. The gas phase etch may further avoid the formation of solid etch by-products which can also deform the delicate features.

Many dielectric etch processes use concurrent polymer deposits on the sidewalls of trenches to ensure the formation of more-or-less vertical sidewalls. Forming trenches in low-K dielectric layers tends to be more complex than forming trenches in high-K dielectrics. Low-K. dielectric layers tend to be more delicate and may be easily deformed. The polymer deposits may be relied on more heavily to vertically confine a low-K dielectric etch process. In order to maintain the desirably low dielectric constant, the polymer ought to be effectively removed after the etch process is completed. The removal of the sidewall polymer must be completed substantially without altering the dielectric constant of the patterned low-K dielectric layer.

Current methods of removing the residual polymer involve liquid etchant or a dry oxygen etch. The liquid etchants can damage narrow low-K dielectric lines as a result of their lower structural integrity. The damage results from the forces caused by the surface tension of the liquid. Dry oxygen-based etches avoid this pitfall. However, the presence of oxygen causes some oxidation of the low-K dielectric lines, and this oxidation raises the dielectric constant (K) of the lines. Methods presented herein use alternative gas phase etch processes having essentially no oxygen, content in embodiments of the invention. The property of having the substrate processing region essentially devoid of oxygen means, herein, that essentially no precursors are intentionally introduced which have oxygen content (e.g. NO₂, O₂, CO₂ etc, are ideally not present).

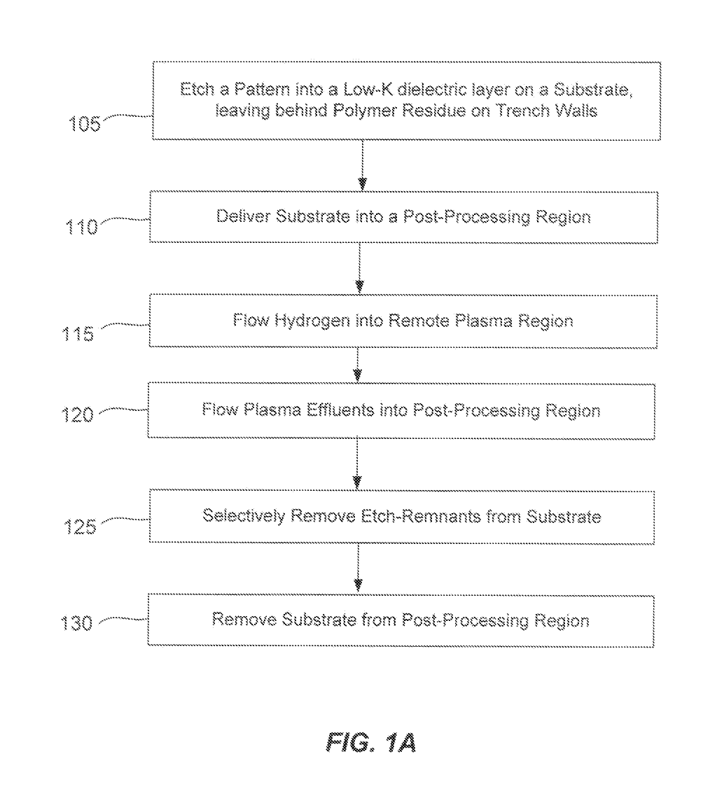

In order to better understand and appreciate the invention, reference is now made to FIGS. 1A and 1B, which are flow charts of residue removal processes according to disclosed embodiments. A low-K dielectric layer is deposited on a substrate and patterned (operation 105) to form a trench in the low-K layer. The patterning process leaves some polymer residue on the surface, for example, on the interior walls of the trench. The substrate may be referred to herein as a patterned substrate at this stage and for the remainder of the process. In operation 110, the patterned substrate is transferred to a processing chamber and placed within a “post-processing” region within (which may be simply referred to as the substrate processing region, for simplicity). As discussed in greater detail in the exemplary equipment section, the processing chamber has a remote plasma region in addition to the substrate processing region. A precursor may be excited in the remote plasma region and excited plasma effluents may be passed through a showerhead into the substrate processing region to remove material horn the patterned substrate. In this particular example, molecular hydrogen (H₂) is flowed into the remote plasma region (operation 115) to be excited and the plasma effluents are passed into the substrate processing region (operation 120) to interact with the patterned substrate. The plasma effluents created hereby have been found to remove polymer residue without the prior art side effects of increasing dielectric constant and/or decreasing the width of dielectric features. The etch process (operation 125) has been found to selectively remove polymeric material (CₓF_{y}) while sparing the low-K dielectric material. The patterned substrate may then be removed from the substrate processing region, in operation 130.

A fluorine-containing precursor has been found to further improve the polymer selectivity of the etch process when flowed into the remote plasma region with the molecular hydrogen (H₂). Such a fluorine-containing precursor may be added to the molecular hydrogen in embodiments of the invention. The fluorine-containing precursor may be at least one of atomic fluorine, diatomic fluorine, bromine trifluoride, chlorine trifluoride, nitrogen trifluoride, hydrogen fluoride, fluorinated hydrocarbons, sulfur hexafluoride and xenon difluoride. Though molecular hydrogen was given in this example, other sources of hydrogen may he used to augment or replace the exemplary source. In general, a hydrogen-containing precursor may be used and the hydrogen-containing precursor may comprise at least one of hydrogen (H₂), methane (CH₄), ethane (C₂H₆) or propane (C₃H₈). The remote plasma region may be essentially devoid of oxygen (in O₂ or in other forms) in embodiments of the invention. The substrate processing region may also be essentially devoid of oxygen, in embodiments, in order to avoid oxidizing and raising the dielectric constant of the patterned low-K dielectric layer.

FIG. 1B represents a second example of an etch residue removal process. A low-K dielectric layer is again deposited on a substrate and patterned (operation 155) to form a trench in the low-K layer. Polymer residue is left on the surface at least on the interior wall of the trench. In operation 160, the patterned substrate is transferred to a processing chamber and placed within a substrate processing region. In this ease, nitrogen trifluoride (NF₃) is flowed into the remote plasma region (operation 165) to be excited and the plasma effluents are passed into the substrate processing region and combined with molecular hydrogen (H₂) flowed directly to the substrate processing region (operation 170). The combination of plasma effluents and molecular hydrogen (H₂) remove etch remnants front the patterned substrate (operation 175). The combination of plasma effluents and molecular hydrogen (not directly excited in a plasma) has been found to remove polymer residue without the prior art side effects of increasing dielectric constant anchor decreasing the width of dielectric features. The etch process (operation 175) has been found to selectively remove polymeric material (CₓF_{y}) while sparing the low-K dielectric material. The patterned substrate may then be removed from the substrate processing region in operation 180.

The separate plasma region may he referred to as a remote plasma region herein and may be within a distinct module from the processing chamber or a compartment within the processing chamber. In one embodiment, a hydrogen-containing precursor is flowed into the remote plasma region and effluents are passed into the substrate processing region. In another embodiment, both a fluorine-containing precursor and a hydrogen-containing precursor are flowed into the plasma region and plasma effluents passed into the substrate processing region. Lastly, a fluorine-containing precursor may be passed into the remote plasma region and plasma effluents passed into the substrate processing region to combine with unexcited hydrogen-containing precursor.

The flow rate of the hydrogen-containing precursor and the fluorine-containing precursor may be selected such that the atomic flow ratio is low relative to the flow rate of the hydrogen to effect a high atomic flow ratio H:F as will be quantified shortly. Atomic flow ratio is calculated from the gas flow rate of each precursor gas and the total number of each atom per molecule. In the embodiment wherein one precursor is H₂ and the other is NF₃, each molecule of hydrogen includes two hydrogen atoms whereas each molecule of nitrogen trifluoride includes three fluorine atoms. Using mass flow controllers to maintain a gas flow ratio (H₂:NF₃) above, e.g. 30:1, will result in an atomic flow ratio (H:F) of above 20:1. The atomic flow ratio includes contributions from all precursors entering the remote plasma region and more directly into the substrate processing region. The atomic flow ratio (H:F) of the precursors is greater than or about 20:1, greater than or about 25:1 or greater than or about 30:1 in embodiments of the invention. The etch selectivity (polymer residue:low-K dielectric) may be greater than or about 30:1, greater than, or about 50:1 or greater than or about 80:1 in disclosed embodiments.

The fluorine-containing precursor and/or the hydrogen-containing precursor may further include one or more relatively inert gases such as He, N₂, Ar, or the like. The inert gas can be used to improve plasma stability and/or to carry liquid precursors to the remote plasma region. Flow rates and ratios of the different gases may be used to control etch rates and etch selectivity. In an embodiment, the fluorine-containing gas includes NF₃ at a flow rate of between about 1 sccm (standard cubic centimeters per minute) and 30 sccm, H₂ at a flow rate of between about 500 sccm and 5,000 sccm. He at a flow rate of between about 0 sccm and 3000 sccm, and Ar at a flow rate of between about 0 sccm and 3000 sccm. One of ordinary skill in the art would recognize that other gases and/or flows may be used depending on a number of factors including processing chamber configuration, substrate size, geometry and layout of features being etched, and the like. The flow rate of the fluorine-containing gas may be less than or about 30 sccm, less than or about 20 sccm, less than or about 15 sccm or less than or about 10 sccm in disclosed embodiments. Lower flow rates of the fluorine-containing gas will generally increase the polymer residue selectivity. The flow rate of the hydrogen-containing gas may be greater than or about 300 sccm, greater than or about 500 sccm greater than or about 1000 sccm or greater than or about 2000 sccm in disclosed embodiments, increasing the flow rate of the hydrogen-containing precursor generally increases polymer residue selectivity. The atomic flow ratio H:F should be kept high to reduce or eliminate solid residue formation on silicon oxide or a low-K dielectric layer. The formation of solid residue consumes some silicon oxide based dielectric which reduces the polymer residue selectivity of the etch process.

The method also includes applying energy to the fluorine-containing precursor and/or the hydrogen-containing precursor while they are in the remote plasma region to generate the plasma effluents. As would be appreciated by one of ordinary skill in the art, the plasma may include a number of charged and neutral species including radicals and ions. The plasma may be generated using known techniques (e.g., RF, capacitively coupled, inductively coupled, and the like). In an embodiment, the plasma power is applied using a capacitively-coupled plasma unit at a source power of between about 10 watts and about 15,000 watts and a pressure of between about 0.2 Torr and about 20 Torr. The capacitively-coupled plasma unit may be disposed remote from a gas reaction region of the processing chamber. For example, the capacitively-coupled plasma unit and the plasma generation region may be separated from the gas reaction region by an ion suppressor.

An ion suppressor may be used to filter ions from the plasma effluents during transit from the remote plasma region to the substrate processing region in embodiments of the invention. The ion suppressor functions to reduce or eliminate ionically charged species traveling from the plasma generation region to the substrate. Uncharged neutral and radical species may pass through the openings in the ion suppressor to react at the substrate, it should be noted that complete elimination of ionically charged species in the reaction region surrounding the substrate is not always the desired goal. In many instances, ionic species are required to reach the substrate in order to etch the polymer residue. In these instances, the ion suppressor helps control, the concentration of ionic species in the reaction region at a level that assists the process. The substrate processing region may be plasma-free during the etching of the patterned substrate. Confining plasma to the remote plasma region along with using an ion suppressor increases the selectivity of the polymer residue etch. These precautions reduce any reduction of the width of low-K dielectric features on the patterned substrate.

In accordance with some embodiments of the invention, an ion suppressor as described in the exemplary equipment section may be used to provide radical and/or neutral species for selectively etching substrates. In one embodiment, for example, an ion suppressor is used to provide fluorine and hydrogen containing plasma effluents to selectively etch polymer residue from sidewalls of trenches formed in a low-K dielectric layer. The ion suppressor may be used to provide a reactive gas having a higher concentration of radicals than ions. When most of the charged particles of a plasma are filtered or removed by the ion suppressor, the substrate is not necessarily biased during the etch process. Such a process using radicals and other neutral species can reduce plasma damage compared to conventional plasma etch processes that include sputtering and bombardment. Embodiments of the present invention are also advantageous over conventional wet etch processes where surface tension of liquids can cause bending and peeling of small features.

Blanket wafers of silicon oxide, silicon and silicon nitride were used to quantify the etch rates for an exemplary process. A remote plasma was formed from nitrogen trifluoride, hydrogen (H₂), helium and argon and the effluents etched blanket wafers of each of the three films in separate processes. The etch process removed silicon at about, two hundred times the rate of silicon oxide and over two hundred times the rate of silicon nitride for etch rates of about 400 Å/min. In separate experiments, the etch process removed silicon at about five hundred times the rate of silicon oxide and over five hundred times the rate of silicon nitride for etch rates of about 200 Å/min. The etch rate of silicon oxide may be greater than or about 1000 Å/min, greater than or about 200 Å/min or greater than or about 300 Å/min in disclosed embodiments. The selectivity, tire non-local plasma, the controlled ionic concentration and the lack of solid byproducts, each make these etch processes well suited for delicately removing or trimming silicon structures removing little or no silicon oxide and little or no silicon nitride.

The temperature of the substrate is greater than 0° C. and less than or about 300° C. during the polymer residue removal process. At the high end of this substrate temperature range, the polymer residue etch rate may drop. At the lower end of this substrate temperature range, low-K, dielectrics, silicon oxide and silicon nitride begin to etch and so the selectivity drops, in disclosed embodiments, the temperature of the substrate during the removal processes described herein may be greater than or about 30° C. while less than or about 200° C. or greater than or about 40° C. while less than or about 150° C. The substrate temperature may be below 100° C., below or about 80° C., below or about 65° C. or below or about 50° C. in disclosed embodiments.

The pressure within the substrate processing region may be below or about 10 Torr, below or about 5 Torr, below or about 3 Torr, below or about 2 Torr, below or about 1 Torr or below or about 750 mTorr in disclosed embodiments. In order to ensure adequate etch rate, the pressure may be above or about 0.01 Torr, above or about 0.05 Torr, above or about 0.1 Torr, above or about 0.2 Torr or above or about 0.4 Torr in embodiments of the invention. Any of the upper limits on pressure may be combined with lower limits to form additional embodiments. Plasma power applied to the remote plasma region can be a variety of frequencies or a combination of multiple frequencies. The RP power may be between about 10 watts and about 15,000 watts, between, about 200 watts and about 10,000 watts or between about 750 watts and about 7500 watts in different embodiments. The RF frequency applied in the exemplary processing system may be low RF frequencies less than about 500 kHz, high RF frequencies between about 10 MHz and about 15 MHz or microwave frequencies greater than or about 1 GHz in different embodiments.

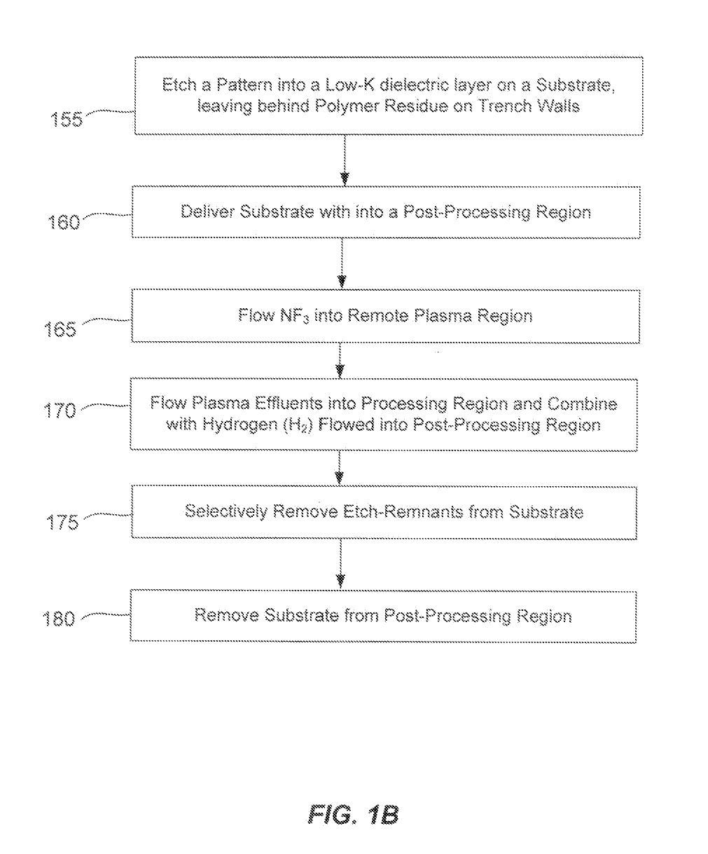

FIG. 2 is a graph showing dielectric constant and residue removal efficiency for different conditions of the removal process according to embodiments of the invention. The dielectric constant of a low-K dielectric layer prior to etching is about 2.24. The low-K dielectric layer is then etched using polymer sidewall protective material. After the etch process, the residual polymer is removed using a variety of polymer residue removal processes. Prior art methods often rely on ozone. Flowing ozone through the remote plasma region creates ozone which passes into the substrate processing region and interacts with the patterned low-K dielectric layer. The experiments show that using molecular oxygen (O₂) as a precursor significantly increases the dielectric constant of the patterned low-K dielectric to between 2.4 and 2.6. Flowing only molecular hydrogen (H₂) into the remote plasma region results in similar removal efficiency of polymer residue, but a much more desirable retention of low dielectric constant. The initial dielectric constant was between 2.2 and 2.3 and the dielectric constant remains in this range after the molecular hydrogen (H₂) based removal process. Further including nitrogen trifluoride (NF₃) flowed into the remote plasma region retains the beneficial dielectric constant effect, while improving the removal efficiency by about a factor often.

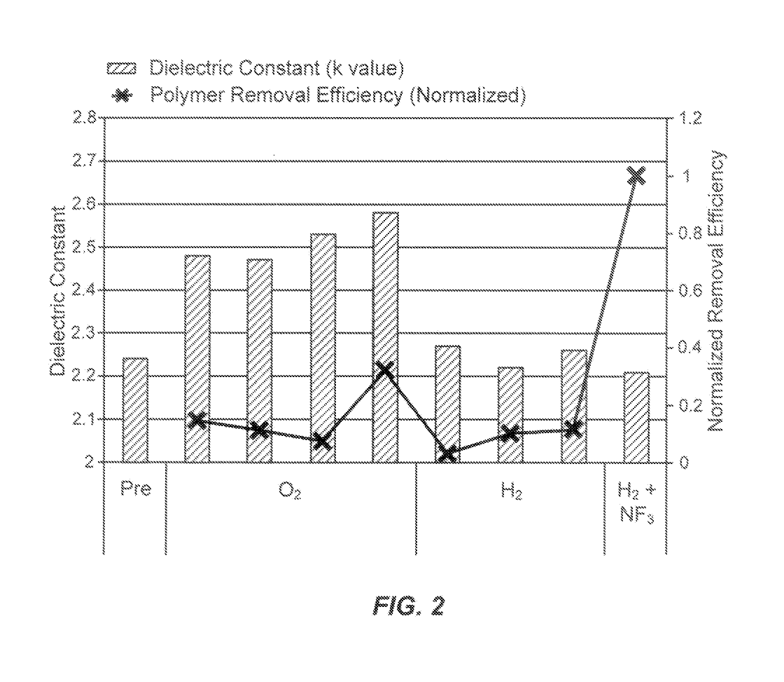

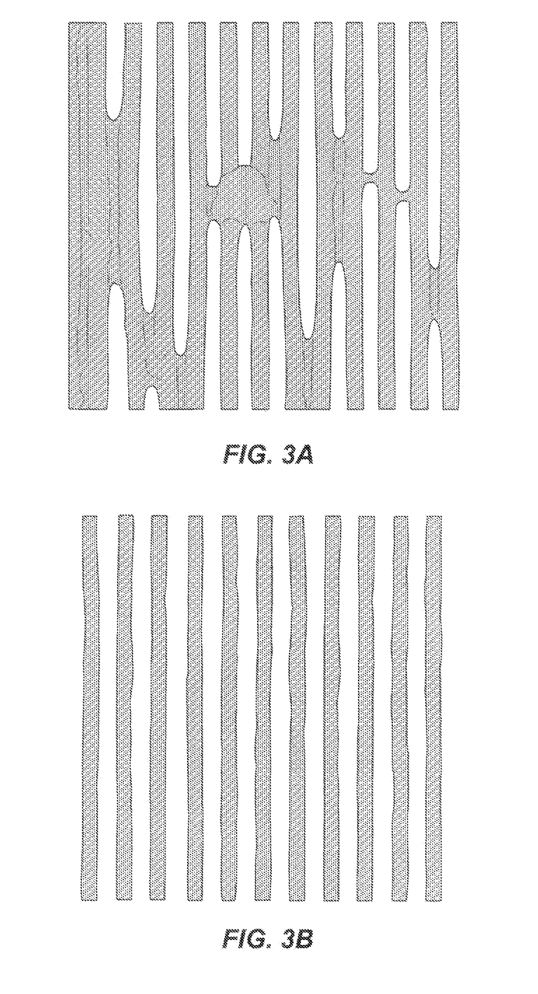

FIG. 3A is a schematic of a top SEM view of low-K dielectric lines with etch residue present and FIG. 3B is a similar schematic alter the etch residue has been removed with a removal process as described herein. For the removal process, both molecular hydrogen (H₂) arid nitrogen trifluoride (NF₃) were flowed into the remote plasma region and plasma effluents were formed and transferred into the substrate processing region. The polymer residue was substantially removed by the plasma effluents and the linewidths of the low-K dielectric features were not measurably reduced.

Additional process parameters are disclosed in the course of describing an exemplary processing chamber and system.

### Exemplary Processing System

Processing chambers that may implement embodiments of the present invention may be included within processing platforms such as the CENTURA® and PRODUCER® systems, available from Applied Materials, Inc. of Santa Clara, Calif. Examples of substrate processing chambers that can be used with exemplary methods of the invention may include those shown and described in co-assigned U.S. Provisional Patent App. No. 60/803,499 to Lubomirsky et at, filed May 30,2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

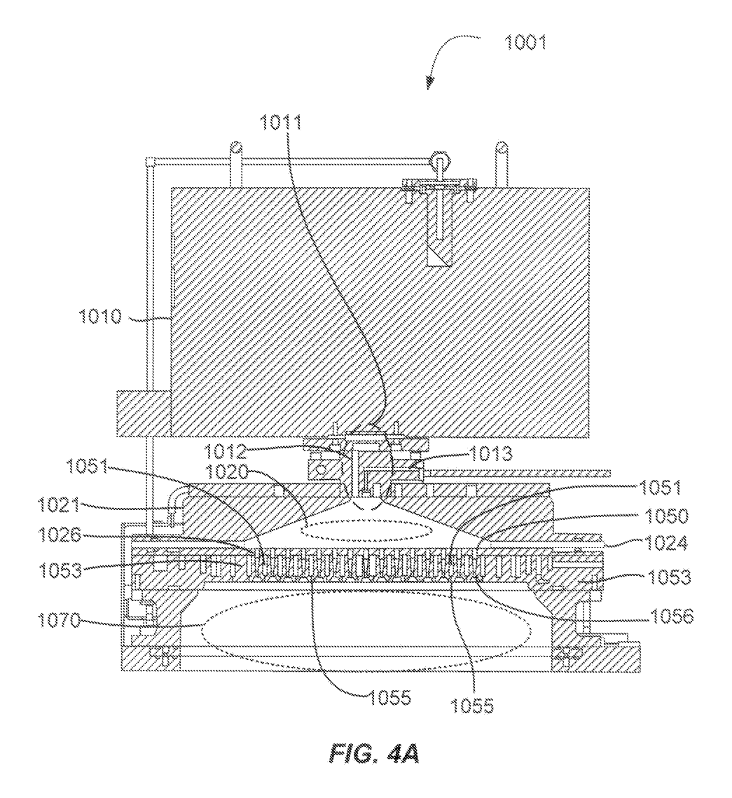

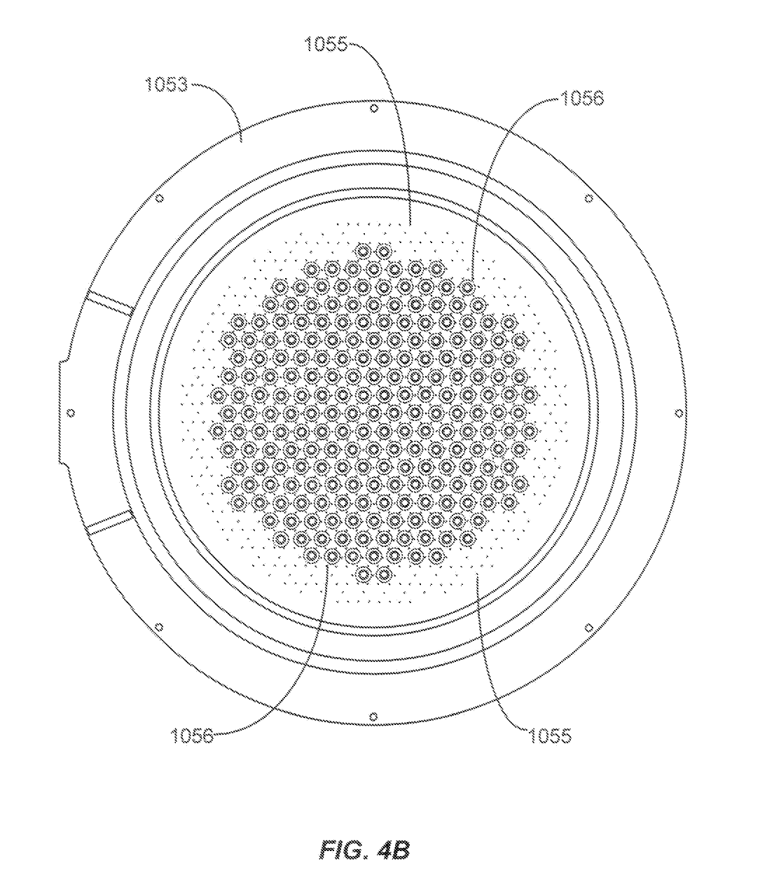

FIG. 4A is a substrate processing chamber 1001 according to disclosed embodiments. A remote plasma system 1010 may process the fluorine-containing precursor which then travels through a gas inlet assembly 1011. Two distinct gas supply channels arc visible within the gas inlet assembly 1011. A first channel 1012 carries a gas that passes through the remote plasma system 1010 (RPS), while a second channel 1013 bypasses the remote plasma system 1010. Either channel may be used for the fluorine-containing precursor, in embodiments. On the other hand, the first channel 1012 may be used for the process gas and the second channel 1013 may be used for a treatment gas. The lid (or conductive top portion) 1021 and a perforated partition 1053 are shown with an insulating ring 1024 in between, which allows an AC potential to be applied to the lid 1021 relative to perforated partition 1053. The AC potential strikes a plasma in chamber plasma region 1020. The process gas may travel through first channel 1012 into chamber plasma region 1020 and may be excited by a plasma in chamber plasma region 1020 alone or in combination with remote plasma system 1010. If the process gas (the fluorine-containing precursor) flows through second channel 1013, then only the chamber plasma region 1020 is used for excitation. The combination of chamber plasma region 1020 and/or remote plasma system 1010 may be referred to as a remote plasma system herein. The perforated partition (also referred to as a showerhead) 1053 separates chamber plasma region 1020 from a substrate processing region 1070 beneath showerhead 1053. Showerhead 1053 allows a plasma present in chamber plasma region 1020 to avoid directly exciting gases in substrate processing region 1070, while still allowing excited species to travel from chamber plasma region 1020 into substrate processing region 1070.

Showerhead 1053 is positioned between chamber plasma region 1020 and substrate processing region 1070 and allows plasma effluents (excited derivatives of precursors or other gases) created within remote plasma system 1010 and/or chamber plasma region 1020 to pass through a plurality of through-holes 1050 that traverse the thickness of the plate. The showerhead 1053 also has one or more hollow volumes 1051 which can be filled with a precursor in the form of a vapor or gas (such as a silicon-containing precursor) and pass through small holes 1055 into substrate processing region 1070 but not directly into chamber plasma region 1020. Showerhead 1053 is thicker than the length of the smallest diameter 1050 of the through-holes 1056 in this disclosed embodiment. In order to maintain a significant concentration of excited species penetrating from chamber plasma region 1020 to substrate processing region 1070, the length 1026 of the smallest diameter 1050 of the through-holes may be restricted by forming larger diameter portions of through-holes 1056 part way through the showerhead 1053. The length of the smallest diameter 1050 of the through-holes 1056 may be the same order of magnitude as the smallest diameter of the through-holes 1056 or less in disclosed embodiments.

Showerhead 1053 may be configured to serve the purpose of an ion suppressor as shown in FIG. 4A. Alternatively, a separate processing chamber element may be included (not shown) which suppresses the ion concentration traveling into substrate processing region 1070. Lid 1021 and showerhead 1053 may function as a first electrode and second electrode, respectively, so that lid 1021 and showerhead 1053 may receive different electric voltages. In these configurations, electrical power (e.g., RF power) may be applied to lid 1021, showerhead 1053, or both. For example, electrical power may he applied to lid 1021 while showerhead 1053 (serving as ion suppressor) is grounded. The substrate processing system may include a RF generator that provides electrical power to the lid and/or showerhead 1053. The voltage applied to lid 1021 may facilitate a uniform distribution of plasma (i.e., reduce localized plasma) within chamber plasma region 1020. To enable the formation of a plasma in chamber plasma region 1020, insulating ring 1024 may electrically insulate lid 1021 from showerhead 1053. Insulating ring 1024 may be made from a ceramic and may have a high breakdown voltage to avoid sparking. Portions of substrate processing chamber 1001 near the capacitively-coupled plasma components just described may further include a cooling unit (not shown) that includes one or more cooling field channels to cool surfaces exposed to the plasma with a circulating coolant (e.g., water).

In the embodiment shown, showerhead 1053 may distribute (via through-holes 1056) process gases which contain fluorine and/or hydrogen and/or plasma effluents of such process gases upon excitation by a plasma in chamber plasma region 1020. In embodiments, the process gas introduced into the remote plasma system 1010 and/or chamber plasma region 1020 may contain fluorine (e.g., F₂, NF₃ or XeF₂). The process gas may also include a carrier gas such as helium, argon, nitrogen (N₂), etc. Plasma effluents may include looked or neutral derivatives of the process gas and may also he referred to herein as radical-fluorine referring to the atomic constituent of the process gas introduced.

Through-holes 1056 are configured to suppress the migration of ionically-charged species out of the chamber plasma region 1020 while allowing uncharged neutral or radical species to pass through showerhead 1053 into substrate processing region 1070. These uncharged species may include highly reactive species that are transported with less-reactive carrier gas by through-holes 1056. As noted above, the migration, of ionic species by through-holes 1056 may be reduced, and in some instances completely suppressed. Controlling the amount of ionic species passing through showerhead 1053 provides increased control over the gas mixture brought into contact with the underlying wafer substrate, which in turn increases control of the deposition and/or etch characteristics of the gas mixture. For example, adjustments in the ion concentration of the gas mixture can significantly alter its etch selectivity.

In embodiments, the number of through-boles 1056 may be between about 60 and about 2000. Through-holes 1056 may have a variety of shapes but are most easily made round. The smallest diameter 1050 of through-holes 1056 may be between about 0.5 mm and about 20 mm or between about 1 mm and about 6 mm in disclosed embodiments. There is also latitude in choosing the cross-sectional shape of through-holes, which may he made conical, cylindrical or combinations of the two shapes. The number of small holes 1055 used to introduce unexcited precursors into substrate processing region 1070 may be between about 100 and about 5000 or between about 500 and about 2000 in different embodiments. The diameter of the small holes 1055 may he between about 0.1 mm and about 2 mm.

Through-holes 1056 may be configured, to control the passage of the plasma-activated gas (i.e., the ionic, radical, and/or neutral species) through showerhead 1053. For example, the aspect ratio of the holes (i.e., the hole diameter to length) and/or the geometry of the holes may be controlled so that the flow of ionically-charged species in the activated gas passing through showerhead 1053 is reduced. Through-holes 1056 in showerhead 1053 may include a tapered portion that faces chamber plasma region 1020, and a cylindrical portion that faces substrate processing region 1070. The cylindrical portion may he proportioned and dimensioned to control the flow of ionic species passing into substrate processing region 1070. An adjustable electrical bias may also be applied to showerhead 1053 as an additional means to control the flow of ionic species through showerhead 1053.

Alternatively, through-holes 1056 may have a smaller inner diameter (ID) toward the top surface of showerhead 1053 and a larger ID toward the bottom surface. In addition, the bottom edge of through-holes 1056 may be chamfered to help evenly distribute the plasma effluents in substrate processing region 1070 as the plasma effluents exit the showerhead and thereby promote even distribution of the plasma effluents and precursor gases. The smaller ID may be placed at a variety of locations along through-holes 1056 and still allow showerhead 1053 to reduce the ion density within substrate processing region 1070. The reduction in ion density results from an increase in the number of collisions with walls prior to entry into substrate processing region 1070. Each collision increases the probability that an ion is neutralized by the acquisition or loss of an electron from the wall. Generally speaking, the smaller ID of through-holes 1056 may be between about 0.2 mm and about 20 mm. In other embodiments, the smaller ID may be between about 1 mm and 6 mm or between about 0.2 mm and about 5 mm. Further, aspect ratios of the through-holes 1056 (i.e., the smaller ID to hole length) may be approximately 1 to 20. The smaller ID of the through-holes may be the minimum ID found along the length of the through-holes. The cross sectional shape of through-holes 1056 may be generally cylindrical, conical, or any combination thereof.

FIG. 4B is a bottom view of a showerhead 1053 for use with a processing chamber according to disclosed embodiments. Showerhead 1053 corresponds with the showerhead shown in FIG. 4A. Through-holes 1056 are depicted with a larger inner-diameter (ID) on the bottom of showerhead 1053 and a smaller ID at the top. Small holes 1055 are distributed substantially evenly over the surface of the showerhead, even amongst the through-boles 1056 which helps to provide more even mixing than other embodiments described herein.

An exemplary patterned substrate may be supported by a pedestal (not shown) within substrate processing region 1070 when fluorine-containing plasma effluents and hydrogen-containing plasma effluents arrive through through-holes 1056 in showerhead 1053. Though substrate processing region 1070 may be equipped to support a plasma for other processes such as curing, no plasma is present during the etching of patterned substrate, in embodiments of the invention.

A plasma may be ignited either in chamber plasma region 1020 above showerhead 1053 or substrate processing region 1070 below showerhead 1053. A plasma is present in chamber plasma region 1020 to produce the plasma effluents which contain radical-fluorine and/or radical-hydrogen from an inflow of fluorine-containing precursor and/or hydrogen-containing precursor. An AC voltage typically in the radio frequency (RF) range is applied between the conductive top portion (lid 1021) of the processing chamber and showerhead 1053 to ignite a plasma in chamber plasma region 1020 during deposition. An RF power supply generates a high RF frequency of 13.56 MHz out may also generate other frequencies alone or in combination with the 13.56 MHz frequency.

The top plasma may be left at low or no power when the bottom plasma in the substrate processing region 1070 is turned on to either cure a film or clean the interior surfaces bordering substrate processing region 1070. A plasma in substrate processing region 1070 is ignited by applying an AC voltage between showerhead 1053 and the pedestal or bottom of the chamber. A cleaning gas may be introduced into substrate processing region 1070 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C. ). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The chamber plasma region or a region in a remote plasma system may be referred to as a remote plasma region. In embodiments, the radical precursors (e.g., radical-fluorine and radical-hydrogen) are formed in the remote plasma region and travel into the substrate processing region where the combination preferentially etches silicon. Plasma power may essentially be applied only to the remote plasma region, in embodiments, to ensure that the radical-fluorine and the radical-hydrogen (which together may be referred to as plasma effluents) are not further excited in the substrate processing region.

In embodiments employing a chamber plasma region, the excited plasma effluents are generated in a section of the substrate processing region partitioned from a deposition region. The deposition region, also known herein as the substrate processing region, is where the plasma effluents mix and react to etch the patterned substrate (e.g. a semiconductor wafer). The excited plasma effluents may also be accompanied by inert gases (in the exemplary ease, argon). The substrate processing region may be described herein as “plasma-free” during the etch of the patterned substrate. “Plasma-free” does not necessarily mean the region is devoid of plasma. A relatively low concentration of ionized species and free electrons created within the plasma region do travel through pores (apertures) in the partition (showerhead/ion suppressor) due to the shapes and sizes of through-holes 1056. In some embodiments, there is essentially no concentration of ionized species and free electrons within the substrate processing region. The borders of the plasma in the chamber plasma region are hard to define and may encroach upon the substrate processing region through the apertures in the showerhead. In the case of an inductively-coupled plasma, a small amount of ionization may be effected within the substrate processing region directly. Furthermore, a low intensity plasma may be created in the substrate processing region without eliminating desirable features of the forming film. All causes for a plasma having much lower intensity ion density than the chamber plasma region (or a remote plasma region, for that matter) during the creation of the excited plasma effluents do not deviate from the scope of “plasma-free” as used herein.

Combined flow rates of fluorine-containing precursor and hydrogen-containing precursor into the chamber may account for 0.05% to about 20% by volume of use overall gas mixture; the remainder being carrier gases. The fluorine-containing precursor and the hydrogen-containing precursor are flowed into the remote plasma region, but the plasma effluents have the same volumetric flow ratio, in embodiments. In the case of the fluorine-containing precursor, a purge or carrier gas may be first initiated into the remote plasma region before those of the fluorine-containing gas to stabilize the pressure within the remote plasma region.

Plasma power applied to the remote plasma region can be a variety of frequencies or a combination of multiple frequencies. In the exemplary processing system the plasma is provided by RF power delivered between lid 1021 and showerhead 1053. The RF power may be between about 10 Watts and about 15,000 Watts, between about 10 Watts and about 5000 Watts, between about 10 Watts and about 2000 Watts, between about 200 Watts and about 1800 Watts or between about 750 Watts and about 1500 Watts in different embodiments. The RF frequency applied in the exemplary processing system may be low RF frequencies less than about 200 kHz, high RF frequencies between about 10 MHz and about 15 MHz or microwave frequencies greater than or about 1 GHz in different embodiments. Substrate processing region 1070 can be maintained at a variety of pressures during the flow of carrier gases and plasma effluents into substrate processing region 1070.

In one or more embodiments, the substrate processing chamber 1001 can be integrated into a variety of multi-processing platforms, including the Producer™ GT, Centura™ AP and Endura™ platforms available from Applied Materials, Inc. located in Santa Clara, Calif. Such a processing platform is capable of performing several processing operations without breaking vacuum. Processing chambers that may implement embodiments of the present invention may include dielectric etch chambers or a variety of chemical vapor deposition chambers, among other types of chambers.

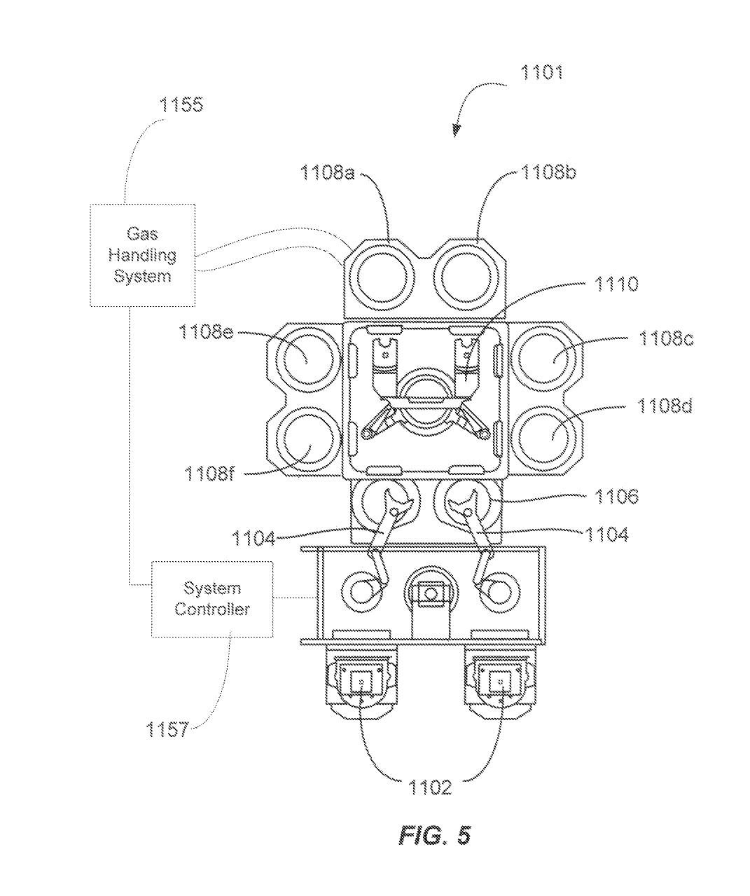

Embodiments of the deposition systems may be incorporated into larger fabrication systems for producing integrated circuit chips. FIG. 5 shows one such system 1101 of deposition, baking and curing chambers according to disclosed embodiments. In the figure, a pair of FOUPs (front opening unified pods) 1102 supply substrate substrates (e.g., 300 mm diameter wafers) that are received by robotic arms 1104 and placed into a low pressure holding areas 1106 before being placed into one of the wafer processing chambers 1108a-f. A second robotic arm 1110 may be used to transport the substrate waters from the low pressure holding areas 1106 to the wafer processing chambers 1108a-f and back. Each water processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation and other substrate processes.

The wafer processing chambers 1108a-f may include one or more system components for depositing, annealing, curing and/or etching a flowable dielectric film on the substrate water. In one configuration, two pairs of the processing chamber (e.g., 1108c-d and 1108e-f) may be used to deposit dielectric material on the substrate, and the third pair of processing chambers (e.g., 1108a-b) may be used to etch the deposited dielectric. In another configuration, all three pairs of chambers (e.g., 1108a-f) may be configured to etch a dielectric film on the substrate. Any one or more of the processes described may be carried out on chamber(s) separated horn the fabrication system shown in different embodiments.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

System controller 1157 is used to control, motors, valves, flow controllers, power supplies and other functions required to carry out process recipes described herein. A gas handling system 1155 may also be controlled by system controller 1157 to introduce gases to one or all of the wafer processing chambers 1108a-f. System controller 1157 may rely on feedback from optical sensors to determine and adjust the position of movable mechanical assemblies in gas handling system 1155 and/or in wafer processing chambers 1108a-f. Mechanical assemblies may include the robot, throttle valves and susceptors which are moved by motors under the control of system controller 1157.

In an exemplary embodiment, system controller 1157 includes a hard disk drive (memory), USB ports, a floppy disk drive and a processor. System controller 1157 includes analog and digital input/output boards, interlace hoards and stepper motor controller boards. Various parts of multi-chamber processing system 1101 which contains substrate processing chamber 1001 are controlled by system controller 1157. The system controller executes system control software in the form of a computer program stored on computer-readable medium such as a hard disk, a floppy disk or a flash memory thumb drive. Other types of memory can also be used. The computer program includes sets of instructions that dictate the timing, mixture of gases, chamber pressure, chamber temperature, RF power levels, suseeptor position, and other parameters of a particular process.

A process for etching, depositing or otherwise processing a film on a substrate or a process for cleaning chamber can be implemented using a computer program product that is executed by the controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is complied, and the resultant compiler code is then linked with an object code of precompiled Microsoft Windows® library routines. To execute the linked, compiled object code the system user invokes the object code, causing the computer system to load the code in memory. The CPU then, reads and executes tire code to perform the tasks identified in the program.

The interface between a user and the controller may be via a touch-sensitive monitor and may also include a mouse and keyboard. In one embodiment two monitors are used, one mounted in the clean room wall for the operators and the other behind the wall for the service technicians. The two monitors may simultaneously display the same information, in which case only one is configured to accept input at a time. To select a particular screen or function, the operator touches a designated area on the display screen with a finger or the mouse. The touched area changes its highlighted color, or a new menu or screen is displayed, confirming the operator's selection.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon” of the patterned substrate is predominantly Si but may include minority concentrations of other elemental constituents such as nitrogen, oxygen, hydrogen, carbon and the like. Exposed “silicon nitride” of the patterned substrate is predominantly Si₃N₄ but may include minority concentrations of other elemental constituents such as oxygen, hydrogen, carbon and the like. Exposed “silicon oxide” of the patterned substrate is predominantly SiO₂ but may include minority concentrations of other elemental constituents such as nitrogen, hydrogen, carbon and the like, in some embodiments, silicon oxide films etched using the methods disclosed herein consist essentially of silicon and oxygen. The term “precursor” is used to refer to any process gas which takes part in a reaction to either remove material from or deposit material onto a surface. “Plasma effluents” describe gas exiting from the chamber plasma region and entering the substrate processing region Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to cither remove material from or deposit material on a surface. “Radical-fluorine” (or “radical-oxygen”) are radical precursors which contain fluorine (or oxygen) but may contain other elemental constituents. The phrase “inert gas” refers to any gas which does not form chemical bonds when etching or being incorporated into a film. Exemplary inert gases include noble gases but may include other gases so long as no chemical bonds are formed when (typically) trace amounts are happed in a film.

The terms “gap” and “trench” axe used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection, As used herein, a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well known processes and elements have not been, described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limbs are also included.

As used herein and in the appended claims, the singular forms “a”, “an” and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other .features, integers, components, steps, acts, or groups.

1. A method of removing polymer residue from a patterned substrate in a substrate processing region of a substrate processing chamber, the method comprising:
flowing a hydrogen-containing precursor into a remote plasma region fluidly coupled to the substrate processing region while forming a remote plasma in the remote plasma region, to produce plasma effluents: and
removing fire polymer residue by flowing the plasma effluents into the substrate processing region.

2. The method of claim 1 further comprising flowing a fluorine-containing precursor into the substrate processing region during the operation of flowing the hydrogen-containing precursor.

3. The method, of claim 1 wherein tire polymer residue comprises a hydrocarbon.

4. The method of claim 1 wherein removing the polymer residue comprises removing the polymer residue from the substantially vertical sidewall of a patterned low-K dielectric layer.

5. The method of claim 1 wherein removing the polymer residue comprises removing the polymer residue from a low-K dielectric layer having a dielectric constant below or about 2.5.

6. The method of claim 1 wherein the temperature of die patterned substrate is greater than or about 0° C. and less than or about 300° C.

7. The method of claim 1 wherein the plasma power is between about 10 watts and about 15,000 watts.

8. The method of claim 1 wherein the pressure within the substrate processing region is above or about 0.01 Torr and below or about 10 Torr.

9. The method of claim 2 wherein an atomic flow ratio of the precursors is greater than or about 20:1 H:F.

10. The method of claim 1 wherein the substrate processing region is plasma-free during the operation of removing the residual polymer.

11. The method of claim 1 wherein the fluorine-containing precursor comprises a precursor selected from the group consisting of atomic fluorine, diatomic fluorine, bromine trifluoride, chlorine trifluoride, nitrogen trifluoride, hydrogen fluoride, fluorinated hydrocarbons, sulfur hexafluoride and xenon difluoride.

12. The method of claim 1 wherein the hydrogen-containing precursor comprises hydrogen (H₂), methane (CH₄), ethane (C₂H₆) or propane (C₃H₈).

13. The method of claim 1 wherein the substrate processing region is essentially devoid of oxygen during the operation of removing the polymer residue.

14. The method of claim 1 wherein there are essentially no ionized species or free electrons within the substrate processing region during the operation of renewing the polymer residue.

15. The method of claim 1 wherein the minimum ID of the through-holes in die showerhead is between about 0.2 mm. and about 5 mm.

16. A method of removing polymer residue from a patterned substrate in a substrate processing region of a substrate processing chamber, the method comprising;
flowing a fluorine-containing precursor into a remote plasma region fluidly coupled to the substrate processing region while forming a remote plasma in the remote plasma region to produce plasma effluents;
flowing a hydrogen-containing precursor into the substrate processing chamber, wherein the hydrogen-containing precursor flows directly into the substrate processing region without first passing through the remote plasma region, and
removing the polymer residue by combining the plasma effluents with the hydrogen-containing precursor in the substrate processing region.

17. The method of claim 16 wherein the hydrogen-containing precursor comprises one of hydrogen (H₂), methane (CH₄), ethane (C₂H₆) or propane (C₃H₂).

18. The method of claim 16 wherein the substrate processing region is essentially devoid of oxygen during the operation of removing the polymer residue.

19. The method of claim 16 wherein removing the polymer residue comprises removing the polymer residue from a low-K dielectric layer having a dielectric constant below or about 2.5.

20. The method of claim 16 wherein the fluorine-containing precursor comprises a precursor selected from the group consisting of atomic fluorine, diatomic fluorine, bromine trifluoride, chlorine trifluoride, nitrogen trifluoride, hydrogen fluoride, fluorinated hydrocarbons, sulfur hexafluoride and xenon difluoride.
